(19) United States
(12) Patent Application Publication
(10) Pub. No.: US 2013/0093060 A1
(43) Pub. Date: Apr. 18, 2013

(54) METHOD FOR PRODUCING SILICON WAFER AND SILICON WAFER

(71) Applicants: Tetsuya Oka, Annaka (JP); Koji Ebara, Annaka (JP); Shuji Takahashi, Takasaki (JP)

(72) Inventors: Tetsuya Oka, Annaka (JP); Koji Ebara, Annaka (JP); Shuji Takahashi, Takasaki (JP)

(73) Assignee: SHIN-ETSU HANDOTAI CO., LTD., Tokyo (JP)

(21) Appl. No.: 13/704,905

(22) PCT Filed: Jun. 7, 2011
(86) PCT No.: PCT/JP2011/003188

§ 371 Date: Dec. 17, 2012

(30) Foreign Application Priority Data
Jul. 14, 2010 (JP) 2010-159550

(51) Int. Cl. H01L 21/26; H01L 29/06

(52) U.S. Cl. CPC H01L 21/26; H01L 29/0684
USPC 257/618; 438/795; 438/14

(57) ABSTRACT

A silicon wafer and method for producing a silicon wafer, including at least: a first heat treatment process in which rapid heat treatment is performed on the wafer by using a rapid heating/cooling apparatus in an atmosphere containing at least one of nitride film formation atmospheric gas, rare gas, and oxidizing gas at a temperature higher than 1300° C. and lower than or equal to a silicon melting point for 1 to 60 seconds; and a second heat treatment process in which temperature and atmosphere are controlled to suppress generation of a defect caused by a vacancy in the wafer and rapid heat treatment is performed on the wafer. Therefore, RIE defects such as oxide precipitates, COPs, and OSFs are not present at a depth of at least 1 μm from the surface, which becomes a device fabrication region, and the lifetime is 500 μsec or longer.

### TECHNICAL FIELD

The present invention relates to a method for producing a silicon wafer and a silicon wafer produced by this method.

### BACKGROUND ART

In recent years, as a device has become finer with an increase in the packing density of a semiconductor circuit, the need for a higher-quality silicon single crystal produced by the Czochralski method (hereinafter referred to as the CZ method), the silicon single crystal serving as a substrate of the device, has intensified.

Incidentally, in the silicon single crystal grown by the CZ method, oxygen of the order of 10 to 20 ppma (a conversion factor of JEIDA: Japanese Electronic Industry Development Association is used) generally leaks out of a quartz crucible and is introduced into a silicon crystal at a silicon melt interface.

Then, the state enters a supersaturated state in the course of cooling of the crystal, and the oxygen agglomerates when the crystal temperature becomes 700° C. or lower and forms an oxide precipitate (hereinafter referred to as a grown-in oxide precipitate). However, the size thereof is extremely small and does not degrade the TZDB (Time Zero Dielectric Breakdown) characteristics, which are included in the oxide dielectric breakdown voltage characteristics, and the device characteristics at a shipment stage. It has been found out that defects that are caused by the growth of a single crystal and degrade the oxide dielectric breakdown voltage characteristics and the device characteristics are composite defects generated as a result of the crystal becoming supersaturated with vacancy point defects called vacancy (Vacancy, hereinafter sometimes abbreviated as Va) and interstitial silicon point defects called interstitial-silicon (Interstitial-Si, hereinafter sometimes abbreviated as I), the vacancy point defects and the interstitial silicon point defects which are introduced from crystal melt into a silicon single crystal, in the course of cooling of the crystal and these point defects agglomerating with oxygen, and are grown-in (Grown in) defects such as FPDs, LSTDs, COPs, and OSFs.

Prior to descriptions of these defects, a factor determining the concentrations of Va and I in which Va and I are introduced into a silicon single crystal will be described.

FIG. 4 is a diagram showing a defect region of a silicon single crystal when V/G, which is the ratio of a pulling rate V (mm/min) at the growth of a single crystal to an average value G (° C./mm) of the gradient of the temperature in the crystal in the direction of a pulling axis in the temperature range from a silicon melting point to 1300° C., is varied by varying the pulling rate V (mm/min) at the growth of a single crystal.

In general, the distribution of the temperature in a single crystal depends on a CZ furnace structure (hereinafter referred to as a hot zone (HZ)) and stays about the same even when the pulling rate is varied. It is for this reason that, in the case of CZ furnaces having the same structure, V/G responds only to a change in the pulling rate. That is, the pulling rate V and V/G are approximately directly proportional. Therefore, the pulling rate V is used as the vertical axis of FIG. 4.

In a region in which the pulling rate V is relatively high, grown-in defects such as FPDs, LSTDs, and COPs, which are considered as voids generated as the agglomeration of vacancies that are point defects called vacancy, are present at high densities in almost the entire area in the direction of a crystal diameter, and the region in which these defects are present is called a V-rich region.

Moreover, when the growth rate is decreased, an OSF ring generated on the periphery of the crystal is contracted toward the inside of the crystal and eventually disappears. When the growth rate is further decreased, a neutral (Neutral: hereinafter referred to as N) region where an excess or deficiency of Va and interstitial silicon is small appears. It has been found out that, in the N region, since, although Va and I are distributed unevenly, the concentrations of Va and I are lower than or equal to the saturation concentrations, they do not agglomerate and become defects. The N region is separated into an Nv region in which Va is dominant and an Ni region in which I is dominant.

It has been found out that, in the Nv region, many oxide precipitates (Bulk Micro Defect, hereinafter referred to as BMD) are formed when thermal oxidation treatment is performed and, in the Ni region, almost no oxygen precipitation occurs. A region with a lower growth rate is called an I-Rich region because the region is supersaturated with I, whereby L/D (which is an abbreviation of Large Dislocation: an interstitial dislocation loop, such as an LSEPD or an LEPD) defects, which are considered to be dislocation loops formed as clusters of I, are present therein at a low density.

This makes it possible to obtain a silicon wafer with an extremely small number of defects, the silicon wafer whose entire surface is the N region, by cutting and polishing a single crystal pulled upwardly with the growth rate being controlled in such a way that the entire region from the center of the crystal in a radial direction becomes the N region.

Moreover, when the BMDs described above are generated on a silicon wafer surface that is a device active region, the BMDs affect the device characteristics such as junction leakage; on the other hand, when the BMDs are present in a bulk other than the device active region, the BMDs are useful because they function as gettering sites that capture metal impurities mixed during the device process.

In recent years, as a method for forming BMDs in an Ni region in which no BMDs are generated, a method (rapid heating/rapid cooling heat treatment) by which RTP (Rapid Thermal Process) treatment is performed has been proposed. The RTP treatment is a heat treatment method by which the temperature is raised rapidly from room temperature at the rate of temperature rise of 50° C./sec, for example, in a nitride film formation atmosphere or a mixed gas atmosphere of nitride film formation atmospheric gas and nitride film non-formation atmospheric gas such as rare gas or reducing gas, and a silicon wafer is heated for about several tens of seconds at a temperature of about 1200° C. and is then cooled rapidly at the rate of temperature fall of 50° C./sec, for example.

A mechanism by which BMDS are formed as a result of oxygen precipitation heat treatment being performed after the RTP treatment is described in detail in Patent Document 1 and Patent Document 2. Here, a BMD formation mechanism will be described briefly.

First, in the RTP treatment, Va is injected from the surface of a silicon wafer while a high temperature of 1200° C. is maintained in an atmosphere of N₂, for example, and redistribution of Va due to the diffusion thereof and disappearance with I occur while the temperature range from 1200° C. to 700° C. is cooled at the rate of temperature fall of 5° C./sec, for example. As a result, the state enters a state in which Va is unevenly distributed in the bulk. When the silicon wafer in such a state is heat-treated at 800° C., for example, oxygen is rapidly clustered in a region with a high concentration of Va, but oxygen is not clustered in a region with a low concentration of Va. When heat treatment is then performed in this state at 1000° C., for example, for a given period of time, the clustered oxygen grows, and BMDS are formed.

As described above, when oxygen precipitation heat treatment is performed on the silicon wafer subjected to the RTP treatment, BMDs which are distributed in the depth direction of the silicon wafer are formed in accordance with the concentration profile of Va formed by the RTP treatment. Therefore, it is possible to form a desired Va concentration profile in the silicon wafer by performing the RTP treatment while controlling the conditions thereof such as an atmosphere, a maximum temperature, and the holding time, and it is possible to produce a silicon wafer having a desired DZ width and a desired BMD profile in depth direction by performing oxygen precipitation heat treatment on the silicon wafer thus obtained.

Patent Document 3 discloses the suppression of BMD formation as a result of an oxide film being formed on the surface due to the RTP treatment performed in an atmosphere of oxygen gas and I being injected from an oxide film interface. As described above, the RTP treatment can promote or suppress BMD formation depending on the conditions such as atmospheric gas and the maximum holding temperature.

Since annealing is performed for an extremely short time in such RTP treatment, outward diffusion of oxygen hardly occurs, making it possible to ignore a reduction in oxygen concentration in a surface layer.

Moreover, Patent Document 4 describes a method for performing the RTP treatment on a silicon wafer whose whole surface is an N region by cutting a silicon wafer from a single crystal in an N region in which no agglomeration of Va and I is present.

With this method, since no grown-in defects are present in Si which is a material, it may be possible to make the wafer defect-free easily by the RTP treatment. However, when a silicon wafer whose whole surface is an N region is prepared and, after the RTP treatment, TDDB characteristics, which are time dependent dielectric breakdown characteristics indicating the long-term reliability of an oxide film, are measured, although the TZDB characteristics are hardly degraded in an Nv region of the silicon wafer, the TDDB characteristics are sometimes degraded. As described in Patent Document 5, since a region in which the TDDB characteristics are degraded is an Nv region and a region in which a defect detected by an RIE method is present, it is extremely important to develop a silicon wafer with no RIE defects in a surface layer thereof and a method for producing such a silicon wafer.

A crystal defect evaluation method by this RIE method will be explained.

The RIE method is a method for evaluating a micro crystal defect containing silicon oxide (hereinafter referred to as SiOₓ) in a semiconductor single crystal wafer while providing depth resolution, and a method disclosed in Patent Document 6 is known.

This method makes an evaluation of a crystal defect by performing highly-selective anisotropic etching such as reactive ion etching on a main surface of a wafer in given thickness and detecting a remaining etching residue.

Since a region in which a crystal defect containing SiOₓ is formed and a non-formation region containing no SiOₓ differ in etching rate (the former has a lower etching rate), when the above-described reactive ion etching is performed, a conical hillock having at a vertex a crystal defect containing SiOₓ, is left on the main surface of the wafer. The crystal defect is enhanced in the form of a projection generated by anisotropic etching, making it possible to detect even a micro defect with ease.

Hereinafter, a crystal defect evaluation method disclosed in Patent Document 6 will be described.

An oxide precipitate which is oxygen precipitated as SiOₓ, the oxygen dissolved in a silicon wafer in a supersaturated state, is formed by heat treatment. Then, when etching is performed on the silicon wafer from a main surface of the silicon wafer by anisotropic etching with high selectivity ratio for a BMD contained in the silicon wafer in an atmosphere of a halogen-based gas mixture (for example, HBr/Cl₂/He+O₂) by using a commercially available RIE apparatus, a conical projection caused by the BMD is formed as an etching residue (a hillock). Therefore, a crystal defect can be evaluated based on the hillock. For example, by counting hillocks thus obtained, it is possible to determine the density of BMDs in the silicon wafer in the etched range.

When defects of the wafer surface layer subjected to the heat treatment by the existing heat treatment method were evaluated by the above-described RIE method, it was found out that the defects were not sufficiently annihilated.

### CITATION LIST

### Patent Document

Patent Document 1: Japanese Unexamined Patent Application Publication No. 2001-203210
Patent Document 2: Japanese Unexamined Patent Application Publication No. 2001-503009
Patent Document 3: Japanese Unexamined Patent Application Publication No. 2003-297839
Patent Document 4: Japanese Unexamined Patent Application Publication No. 2001-203210
Patent Document 5: Japanese Unexamined Patent Application Publication No. 2009-249205
Patent Document 6: Japanese Patent No. 3451955

### DISCLOSURE OF INVENTION

### Problem to be Solved by the Invention

When a MOS transistor is fabricated in a device process and a reverse bias is applied to a gate electrode for operation of the MOS transistor, a depletion layer expands. If a defect such as a BMD is present in the depletion layer region, such a defect causes junction leakage. It is for this reason that a grown-in defect typified by a COP, a BMD, and a grown-in oxide precipitate are required not to be present in a wafer surface layer (in particular, a 3-μm region from the surface) which is an operation region in many devices. In general, it is necessary to make the oxygen concentration below the solid solubility limit to annihilate oxygen-related defects such as COPs, OSF nuclei, and oxide precipitates. This can be achieved by a method by which the oxygen concentration of the surface layer is made below the solid solubility limit by performing heat treatment at 1100° C. or higher, for example, and reducing the oxygen concentration of the surface layer due to outward diffusion of oxygen. However, the oxygen concentration of the surface layer is significantly reduced by the outward diffusion of oxygen, resulting in a reduction in mechanical strength of the surface layer.

Furthermore, a minority carrier is required to have a sufficient lifetime in order for the semiconductor device to function properly. The lifetime of the minority carrier (hereinafter referred to as the lifetime) is shortened by the formation of a defect level caused by metal impurities, oxygen precipitation, vacancy, etc. Therefore, to ensure the function of the semiconductor device stably, it is necessary to produce a silicon wafer in such a way that the lifetime is at least 500 μsec or longer.

In view of these circumstances, in the recent devices, a silicon wafer having no oxygen-related grown-in defects and grown-in oxide precipitates in a device operation region, in which the lifetime is 500 μsec or longer and a BMD which becomes a gettering site is precipitated by device heat treatment, is effective.

Through an intensive study, the inventors of the present invention have found out that, by performing the RTP treatment at a temperature higher than 1300° C., it is possible to annihilate RIE defects in a silicon wafer surface layer. However, at the same time, it has been found out that, in the silicon wafer subjected to the RTP treatment at a temperature higher than 1300° C., the lifetime after the heat treatment is greatly shortened. As described earlier, a case in which the lifetime is shorter than 500 μsec becomes a problem because there is a high possibility of a device failure.

In the light of these facts, in order for a device to function properly, it is necessary to provide a silicon wafer with no RIE defects, in which the lifetime is sufficiently long.

The present invention has been made in view of the problems described above, and an object thereof is to provide a method for producing a silicon wafer in which defects (RIE defects) such as an oxide precipitate, a COP, and an OSF, that are detected by an RIE method, are not present at a depth of at least 1 μm from the surface which becomes a device fabrication region and the lifetime is 500 μsec or longer, and a silicon wafer produced by this method.

### Means for Solving Problem

To attain the object described above, the present invention provides a method for producing a silicon wafer, comprising at least: a first heat treatment process in which rapid heat treatment is performed on a silicon wafer cut from a silicon single crystal ingot grown by the Czochralski method by using a rapid heating/rapid cooling apparatus in a first atmosphere containing at least one of nitride film formation atmospheric gas, rare gas, and oxidizing gas at a first temperature that is higher than 1300° C. and is lower than or equal to a silicon melting point for 1 to 60 seconds; and a second heat treatment process in which, after the first heat treatment process, a temperature and an atmosphere are controlled so as to be a second temperature and a second atmosphere that suppress the generation of a defect caused by a vacancy in the silicon wafer and rapid heat treatment is performed on the silicon wafer at the controlled second temperature in the controlled second atmosphere.

By performing such a first heat treatment process, it is possible to annihilate defects detected by an RIE method at a depth of at least 1 μm from the surface of the silicon wafer. Then, by performing the above-described second heat treatment process after the first heat treatment process, it is possible to reduce the concentration of vacancies which are excessively increased in the silicon wafer in the first heat treatment process and suppress the generation of a defect level caused by a vacancy. This makes it possible to prevent the lifetime of a silicon wafer to be produced from being shortened. Moreover, by performing the rapid heat treatment, it is possible to control the precipitation of BMDs in the wafer at the time of device heat treatment effectively.

At this time, it is preferable that, in the second heat treatment process, after the first heat treatment process, the second heat treatment process is performed by lowering the temperature rapidly from the first temperature to the second temperature that is lower than 1300° C. at the rate of temperature fall of 5° C./sec or more but 150° C./sec or less and performing rapid heat treatment on the silicon wafer at the second temperature for 1 to 60 seconds.

As described above, by performing the above-described rapid heat treatment in the second heat treatment process, it is possible to reduce the vacancy concentration in the silicon wafer efficiently and suppress the generation of a defect caused by a vacancy effectively. This makes it possible to prevent reliably the lifetime from being shortened.

At this time, as the second atmosphere in the second heat treatment process, an atmosphere containing at least one of the rare gas and the nitride film formation atmospheric gas can be used, and the second temperature can be set at 300° C. or higher but lower than 1300° C.

By performing such a second heat treatment process, it is possible to reduce the vacancy concentration and suppress the generation of a defect caused by a vacancy adequately. This makes it possible to produce reliably a silicon wafer in which the lifetime is not shortened. Moreover, in an atmosphere containing at least one of the rare gas and the nitride film formation atmospheric gas, it is possible to obtain a silicon wafer in which sufficient BMDs are precipitated in a device fabrication process.

Furthermore, as the second atmosphere in the second heat treatment process, an atmosphere of reducing gas or a gas mixture of the reducing gas and the rare gas can be used, and the second temperature can be set at 300° C. or higher but lower than 900° C.

By performing such a second heat treatment process, it is possible to reduce the vacancy concentration and suppress the generation of a defect caused by a vacancy adequately. This makes it possible to obtain reliably a silicon wafer in which the lifetime is not shortened. Moreover, when the second atmosphere is an atmosphere of the reducing gas or a gas mixture of the reducing gas and the rare gas, it is possible to prevent the generation of a slip dislocation reliably when the temperature is lower than 900° C. and produce a silicon wafer in which BMDs are precipitated satisfactorily.

At this time, as the second atmosphere in the second heat treatment process, an atmosphere of oxidizing gas can be used, and the second temperature can be set at 300° C. or higher but 700° C. or lower or 1100° C. or higher but lower than 1300° C.

By performing such a second heat treatment process, it is possible to annihilate a vacancy by an injection of interstitial silicon and suppress a defect caused by a vacancy adequately. This makes it possible to obtain a silicon wafer with a longer lifetime.

At this time, it is preferable that the silicon wafer is a silicon single crystal wafer cut from a silicon single crystal ingot whose whole surface is an OSF region, an N region, or a region in which the OSF region and the N region are mixed.

By using such a silicon single crystal wafer, a defect is annihilated more easily in the first heat treatment process. Therefore, even when polishing, etching, etc. are performed in a later process, no defect appears in the front surface which becomes a device fabrication region, making it possible to produce a higher-quality silicon wafer.

Moreover, the present invention is a silicon wafer produced by the method of the present invention for producing a silicon wafer, the silicon wafer in which a defect that is detected by an RIE method is not present at a depth of at least 1 μm from the surface of the silicon wafer which becomes a device fabrication region, and the lifetime of the silicon wafer is 500 μsec or longer.

Such a silicon wafer does not suffer a device characteristic failure caused by a defect in a device fabrication region or a shortened lifetime and becomes a high-quality wafer for device fabrication.

### Effect of the Invention

As described above, according to the present invention, since a defect is not present in a surface layer and the lifetime is not shortened, a device failure does not occur, making it possible to produce a high-quality silicon wafer.

### BRIEF DESCRIPTION OF DRAWINGS

FIG. 1 is a schematic diagram showing an example of a silicon single crystal pulling apparatus;

FIG. 2 is a schematic diagram showing an example of a single wafer processing rapid heating/rapid cooling apparatus;

FIG. 3 is a graph showing the relationship between a heat treatment temperature and an atmosphere at and in which heat treatment is performed in an example and a comparative example and the BMD density; and

FIG. 4 is an explanatory diagram showing the relationship between a pulling rate and a defect region in the production of a silicon single crystal.

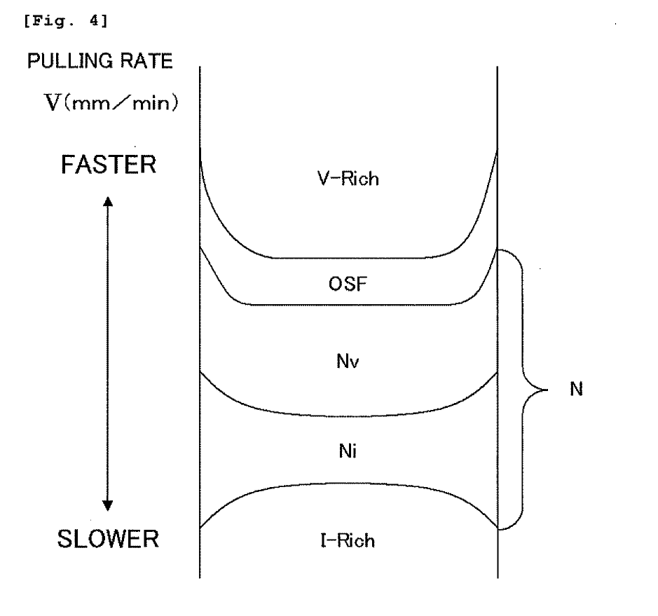

### BEST MODE FOR CARRYING OUT THE INVENTION

The inventors of the present invention have studied intensively to produce a silicon wafer having a surface layer with no defects, in which no device failure occurs.

As a result, it has been found out that, by performing rapid heat treatment at a temperature higher than 1300° C., it is possible to annihilate defects detected by an RIE method to a depth of at least 1 μm from the surface of the a silicon wafer.

In addition, as a result of a further study, it has been found out that, when the lifetime of a silicon wafer on which rapid heat treatment has been performed at a temperature higher than 1300° C. as described above is evaluated, the lifetime is undesirably shortened. The cause is not clear, but it is assumed that, when heat treatment is performed at a temperature higher than 1300° C., a high concentration of vacancies are excessively generated in the wafer and the vacancies agglomerate in the course of cooling or the vacancies unite with other elements present in the wafer, resulting in the generation of a defect level. The shortened lifetime is not desirable because it may become a factor for a reduction in yield in a device process and destabilization of the device function.

It has been found out that, to prevent such a shortened lifetime, defects in a wafer surface layer are annihilated at a temperature higher than 1300° C. and then, as second heat treatment, rapid heat treatment is performed at a second temperature in a second atmosphere for suppressing generation of a defect caused by a vacancy, and the present invention has been completed. This makes it possible to annihilate defects in a surface layer and at the same time prevent a shortened lifetime, making it possible to produce a high-quality silicon wafer with no device failure.

Hereinafter, the present invention will be described in detail as an example of an embodiment with reference to the drawings, but the present invention is not limited thereto.

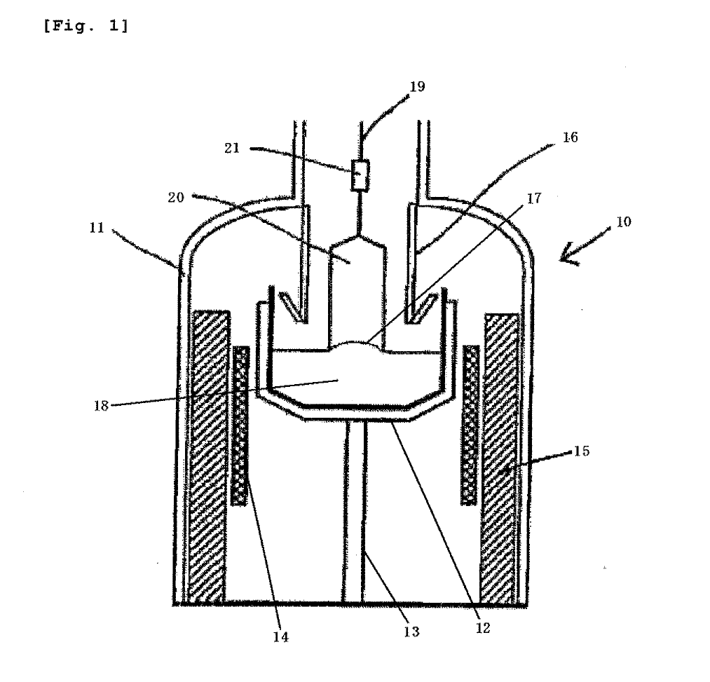

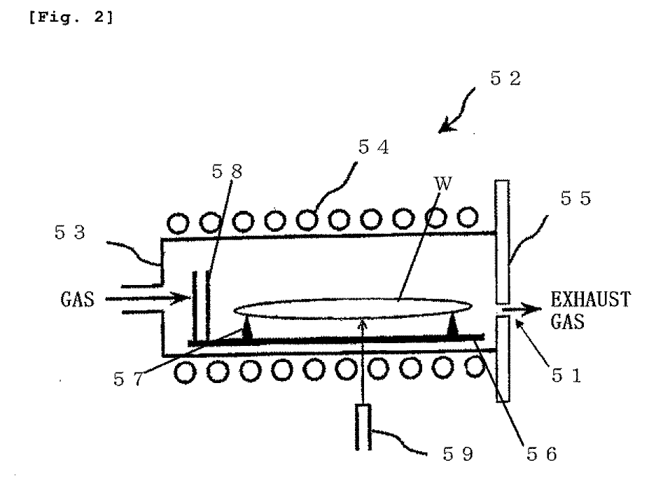

FIG. 1 is a schematic diagram showing a silicon single crystal pulling apparatus. FIG. 2 is a schematic diagram showing a single wafer processing rapid heating/rapid cooling apparatus.

In a production method of the present invention, a silicon single crystal ingot is first grown, and a silicon wafer is cut from the silicon single crystal ingot.

The diameter etc. of a silicon single crystal ingot to be grown is not limited to a particular diameter etc. and can be set at, for example, 150 to 300 mm or larger, and a silicon single crystal ingot can be grown to a desired size for an intended purpose.

Moreover, as for a defect region of a silicon single crystal ingot to be grown, it is possible to grow, for example, a single crystal ingot with a whole surface formed of a V-Rich region, an OSF region, an N region, or a region in which these regions are mixed; preferably, a silicon single crystal ingot whose whole surface is an OSF region, an N region, or a region in which the OSF region and the N region are mixed is grown.

The present invention can reduce defects greatly even in a silicon wafer cut from a silicon single crystal ingot containing a V-Rich region, the silicon wafer in which COPs etc. tend to be generated. Moreover, the present invention is particularly effective for a silicon wafer cut from a silicon single crystal ingot whose whole surface is an OSF region, an N region, or a region in which the OSF region and the N region are mixed because the silicon wafer contains almost no COPs which are most difficult to annihilate, which makes it possible to annihilate defects reliably by rapid heat treatment of the present invention and makes it easy to annihilate also RIE defects in a deeper position.

Here, a single crystal pulling apparatus that can be used in the production method of the present invention will be described.

In FIG. 1, a single crystal pulling apparatus 10 is shown. The single crystal pulling apparatus 10 includes a pull chamber 11, a crucible 12 provided in the pull chamber 11, a heater 14 disposed around the crucible 12, a crucible holding shaft 13 that rotates the crucible 12 and a mechanism (not shown) for rotating the crucible holding shaft 13, a seed chuck 21 holding a silicon seed crystal, a wire 19 pulling the seed chuck 21 upwardly, and a take up mechanism (not shown) rotating or taking up the wire 19. Inside the crucible 12, a quartz crucible is provided on the side where the crucible 12 contains silicon melt (molten metal) 18 therein, and, outside the crucible 12, a graphite crucible is provided. Moreover, a heat insulating material 15 is disposed around the outside of the heater 14.

Moreover, according to the production conditions, an annular graphite cylinder (a gas flow-guide cylinder) 16 can be provided as in FIG. 1, or an annular outside heat insulating material (not shown) can also be provided on the periphery of a solid-liquid interface 17 of a crystal. Furthermore, it is also possible to provide a cylindrical cooling apparatus that cools a single crystal by spraying a cooling gas or keeping out radiant heat.

In addition, it is also possible to use an apparatus of the so-called MCZ method that ensures stable growth of a single crystal by suppressing the convection of melt by providing a magnet (not shown) on the outside of the pull chamber 11 in a horizontal direction and applying a horizontal or vertical magnetic field to the silicon melt 18.

The individual sections of these apparatuses may be similar to those of the existing apparatus, for example.

Hereinafter, an example of a single crystal growth method by the single crystal pulling apparatus 10 described above will be described.

First, silicon high-purity polycrystalline material is melted by being heated to a melting point (about 1420° C.) or higher in the crucible 12. Next, the wire 19 is reeled out to make the tip of the seed crystal contact with virtually the center of the surface of the silicon melt 18 or immerse the tip of the seed crystal therein. Then, the crucible holding shaft 13 is rotated in an appropriate direction and the wire 19 is taken up while being rotated to pull the seed crystal upwardly. In this way, the growth of a silicon single crystal ingot 20 is started.

Then, the pulling rate and the temperature are appropriately adjusted in such a way that a desired defect region is formed, and a silicon single crystal ingot 20 having a virtually cylindrical shape is obtained.

To control the desired pulling rate (growth rate) efficiently, for example, a preliminary test for examining the relationship between a pulling rate and a defect region by growing an ingot at varied pulling rates is conducted in advance, and the pulling rate is then controlled again in a main test based on the relationship, which makes it possible to produce a silicon single crystal ingot in such a way that a desired defect region is obtained.

Then, for example, slicing, polishing and the like are performed on the silicon single crystal ingot produced in this manner, and a silicon wafer can be obtained.

In the present invention, a first heat treatment process is performed in which rapid heat treatment is performed on the obtained silicon wafer by using a rapid heating/rapid cooling apparatus by holding the silicon wafer in a first atmosphere containing at least one of nitride film formation atmospheric gas, rare gas, and oxidizing gas at a first temperature that is higher than 1300° C. and is lower than or equal to the silicon melting point for 1 to 60 seconds.

With this first heat treatment process, at a heat treatment temperature higher than 1300° C., it is possible to annihilate RIE defects reliably in at least 1-μm depth region from the surface of the silicon wafer. This prevents the defects from appearing on the surface which becomes a device fabrication region, making it possible to prevent a device failure.

Moreover, as for the rapid heat treatment time in the first heat treatment process, it is only necessary to perform treatment for 1 to 60 seconds. In particular, by setting an upper limit at 60 seconds, there is almost no decline in the productivity, which prevents an increase in cost, and it is possible to prevent the generation of a slip dislocation during rapid heat treatment reliably. Furthermore, by making outward diffusion of oxygen just right during heat treatment, it is possible to prevent the oxygen concentration from being greatly reduced in the surface layer, which makes it possible to prevent a reduction in mechanical strength.

Moreover, in the atmosphere described above, it is possible to annihilate RIE defects in the wafer surface layer and at the same time form point defects such as new vacancies in the wafer evenly. This greatly promotes BMD formation at the time of device heat treatment etc. in a later process and makes it possible to produce a silicon wafer with high gettering performance. In addition, in an atmosphere containing oxidizing gas, depending on the concentration, BMD formation at the time of device heat treatment is suppressed. As described above, it is possible to control BMD formation at the time of device heat treatment by adjusting the atmosphere.

Moreover, the rapid heating/rapid cooling apparatus that can be used for the rapid heat treatment of the present invention is not limited to a particular apparatus, and an apparatus similar to a commercially available existing apparatus can be used. A schematic diagram of an example of a rapid heating/rapid cooling apparatus that can be used for the rapid heat treatment of the present invention is shown in FIG. 2.

A rapid heating/rapid cooling apparatus 52 has a chamber 53 made of quartz, and rapid heat treatment can be performed on a silicon wafer W in this chamber 53. Heating is performed by heating lamps 54 (for example, halogen lamps) disposed in such a way as to surround the chamber 53 from above and below and from right and left. The heating lamps 54 are configured to be able to control electric power supplied thereto independently.

An automatic shutter 55 is provided on the gas exhaust side and keeps outside air out. The automatic shutter 55 is provided with an unillustrated wafer insertion opening configured to be openable and closable by a gate valve. Moreover, the automatic shutter 55 is provided with a gas exhaust port 51, which makes it possible to adjust the furnace atmosphere.

In addition, the silicon wafer W is placed on a three-point supporting portion 57 formed on a quartz tray 56. On the side of the quartz tray 56 where a gas feed port is provided, a quartz buffer 58 is provided, making it possible to prevent a fed gas such as oxidizing gas, nitriding gas, or Ar gas from blowing directly on the silicon wafer W.

Moreover, in the chamber 53, an unillustrated special window for measuring temperatures is provided, and it is possible to measure the temperature of the silicon wafer W through the special window by a pyrometer 59 provided outside the chamber 53.

In addition, in the present invention, a second heat treatment process is performed in which, after the above-described first heat treatment process, a temperature and an atmosphere are controlled so as to be a second temperature and a second atmosphere that suppress the generation of a defect caused by a vacancy in the silicon wafer and rapid heat treatment is performed on the silicon wafer at the controlled second temperature in the controlled second atmosphere.

With such a second heat treatment process, it is possible to prevent agglomeration of vacancies and the formation of a defect level due to a vacancy and prevent the lifetime from being shortened greatly. This makes it possible to obtain a silicon wafer in which the lifetime after the heat treatment is 500 μsec or longer.

At this time, in the second heat treatment process, after the first heat treatment process, it is preferable to perform the second heat treatment process by lowering the temperature rapidly from the first temperature to the second temperature that is lower than 1300° C. at the rate of temperature fall of 5° C./sec or more but 150° C./sec or less and performing rapid heat treatment on the silicon wafer at the second temperature for 1 to 60 seconds.

By performing the second heat treatment process under the above-described conditions, it is possible to reduce the vacancy concentration and suppress the formation of a defect level due to a vacancy efficiently and prevent a shortened lifetime effectively.

Moreover, it is possible to use, as the second atmosphere in the second heat treatment process, an atmosphere containing at least one of the rare gas and the nitride film formation atmospheric gas and set the second temperature at 300° C. or higher but lower than 1300° C.

In such an atmosphere and at such a temperature of the heat treatment, it is possible to suppress agglomeration of vacancies and the formation of a defect level due to a vacancy more effectively. Furthermore, when the second atmosphere is an atmosphere containing at least one of the rare gas and the nitride film formation atmospheric gas, BMD formation at the time of device heat treatment is further promoted. Moreover, as the second temperature in such an atmosphere, a temperature of 300° C. or higher but 900° or lower or 1100° C. or higher but 1250° C. or lower is particularly desirable. At a temperature in this range, it is possible to further suppress agglomeration of vacancies and perform heat treatment by which the lifetime is scarcely shortened.

In addition, it is also possible to use, as the second atmosphere in the second heat treatment process, an atmosphere of the reducing gas or a gas mixture of the reducing gas and the rare gas and set the second temperature at 300° C. or higher but lower than 900° C.

Also in such an atmosphere and at such a temperature of the heat treatment, it is possible to suppress agglomeration of vacancies more effectively and suppress a vacancy and the formation of a defect level due to a vacancy reliably. Furthermore, in an atmosphere of the reducing gas or a gas mixture of the reducing gas and the rare gas, BMD formation at the time of device heat treatment is further promoted. The second temperature that is lower than 900° C. is desirable because a slip dislocation is rarely generated at such a temperature. Moreover, when the reducing gas is hydrogen, hydrogen is injected into the wafer. The hydrogen causes the formation of a donor by heat treatment in a device process, and such a donor causes a shortened lifetime and a change in the wafer resistivity. In particular, in recent years, the temperature of the heat treatment in the device process has become increasingly lower, and allowing the hydrogen causing the formation of a donor to be distributed in the silicon wafer in high concentration is undesirable. Thus, by performing the second heat treatment process of the present invention in the above-described temperature range of 300° C. or higher but lower than 900° C., the hydrogen presents no problem because injected hydrogen is a low concentration.

Moreover, it is also possible to use, as the second atmosphere in the second heat treatment process, an atmosphere of oxidizing gas and set the second temperature at 300° C. or higher but 700° C. or lower or 1100° C. or higher but lower than 1300° C.

Also in such an atmosphere and at such a temperature of the heat treatment, it is possible to suppress agglomeration of vacancies more effectively and suppress the formation of a defect level due to a vacancy reliably. In the atmosphere of oxidizing gas, at a heat treatment temperature of higher than 700° C. but lower than 1100° C., agglomeration of vacancies is suppressed insufficiently; however, in the above-described temperature range of 300° C. or higher but 700° C. or lower or 1100° C. or higher but lower than 1300° C., it is possible to suppress agglomeration of vacancies effectively and suppress a defect caused by a vacancy reliably.

Here, as the nitride film formation atmospheric gas used in the present invention, N₂ gas or NH₃ gas, for example, can be used, and, as the rare gas, Ar gas, for example, can be used, as the reducing gas, H₂ gas, for example, can be used, and, as the oxidizing gas, gas containing O₂, for example, can be used. However, the gases are not limited to the above-described types of gas.

Incidentally, the second temperature and atmosphere to be controlled in the second heat treatment process are not limited to particular temperature and atmosphere, and may be a temperature and an atmosphere other than conditions described above, that can suppress the generation of a defect caused by a vacancy. Moreover, the second heat treatment process may be performed after the silicon wafer is taken out of the rapid heating/rapid cooling apparatus after the first heat treatment process, and the effect of the present invention can be obtained by performing the second heat treatment process more than once.

The silicon wafer produced by the above-described method of the present invention for producing a silicon wafer is a high-quality wafer for device fabrication, in which a defect detected by an RIE method is not present at a depth of at least 1 μm from the silicon wafer surface that becomes a device fabrication region, and the lifetime of the silicon wafer is 500 μsec or longer.

### EXAMPLE

Hereinafter, the present invention will be described more specifically based on an example and a comparative example; however, the present invention is not limited to these examples.

### Example, Comparative Example

An N-region silicon single crystal ingot (diameter: 12 inches (300 mm), orientation <100>, conductivity type: p-type) was grown while applying a transverse magnetic field by the MCZ method by the silicon single crystal pulling apparatus of FIG. 1, and rapid heat treatment (the first heat treatment process) was performed on a plurality of silicon single crystal wafers cut from the grown ingot in an atmosphere of Ar gas at 1350° C. for 10 seconds by using the rapid heating/rapid cooling apparatus of FIG. 2 (here, Helios manufactured by Mattson Technology, Inc.) to annihilate RIE defects in a wafer surface layer.

Thereafter, cooling was performed at the rate of temperature fall of 30° C./sec until the temperature becomes the second temperature (300 to 1300° C.) that is lower than 1300° C., and heat treatment was performed for 10 seconds in an atmosphere of predetermined gas (an atmosphere of Ar gas, an atmosphere of N₂ gas, an atmosphere of NH₃/Ar gas, an atmosphere of H₂ gas, and an atmosphere of O₂ gas) (the second heat treatment process). Then, wafers whose surfaces were polished to a depth of about 5 μm were formed.

Etching was performed on each of the wafers formed in this manner under each heat treatment condition by using a magnetron RIE apparatus (Centura manufactured by Applied Materials, Inc.). The subsequent measurement of a residual projection after etching by a laser scatting foreign matter inspection apparatus (SP1 manufactured by KLA-Tencor Corporation) and the calculation of the defect density revealed that defects were annihilated in any of these wafers in the first heat treatment process and the defect density was 0.

Moreover, treatment (Chemical Passivation treatment, hereinafter CP treatment) by which a solution of ethanol into which 2 grams of iodine was dropped is applied to an object was performed on other wafers, and the lifetime was measured by a lifetime measuring apparatus (WT-2000 manufactured by SEMILAB Co. Ltd.). The measurement results are shown in Table 1.

TABLE 1

| | Second Temperature | | | | | | | | |
|---|---|---|---|---|---|---|---|---|---|
| Second Atmosphere | 300° C. | 700° C. | 800° C. | 900° C. | 1000° C. | 110° C. | 1250° C. | 1280° C. | 1300° C. |
| Ar | Excellent | Excellent | Excellent | Excellent | Good | Excellent | Excellent | Excellent | Poor |
| N₂ | Excellent | Excellent | Excellent | Excellent | Good | Excellent | Excellent | Good | Poor |
| NH₃/Ar | Excellent | Excellent | Excellent | Excellent | Good | Excellent | Excellent | Good | Poor |
| H₂ | Excellent | Excellent | Excellent | generation | generation | | | | |
| | | | | of slip | of slip | | | | |
| | | | | Fair | Poor | | | | |
| O₂ | Excellent | Excellent | Poor | Poor | Poor | Excellent | Excellent | Excellent | Good |

Ecellent . . . 1000 μsec or longer
Good . . . 700 μsec or longer and shorter than 1000 μsec
Fair . . . 400 μsec or longer and shorter than 700 μsec
Poor . . . shorter than 400 μsec

As shown in Table 1, when the atmosphere was an atmosphere of Ar gas, an atmosphere of N₂ gas, and an atmosphere of NH₃/Ar gas, a good lifetime was measured in the range of 300° C. or higher but lower than 1300° C. Moreover, in an atmosphere of H₂ gas, at 900° C. or higher, the lifetime was shortened and a slip dislocation was generated. Therefore, in an atmosphere of H₂ gas, a temperature that is 300° C. or higher but lower than 900° C. is desirable. Furthermore, in an atmosphere of O₂ gas, the lifetime was shortened in the 800° C.-to-1000° C. range, and, at 300° C. or higher but 700° C. or lower or 1100° C. or higher but lower than 1300° C., the lifetime was not shortened. Therefore, in an atmosphere of O₂ gas, the temperature range of 300° C. or higher but 700° C. or lower or 1100° C. or higher but lower than 1300° C. is desirable.

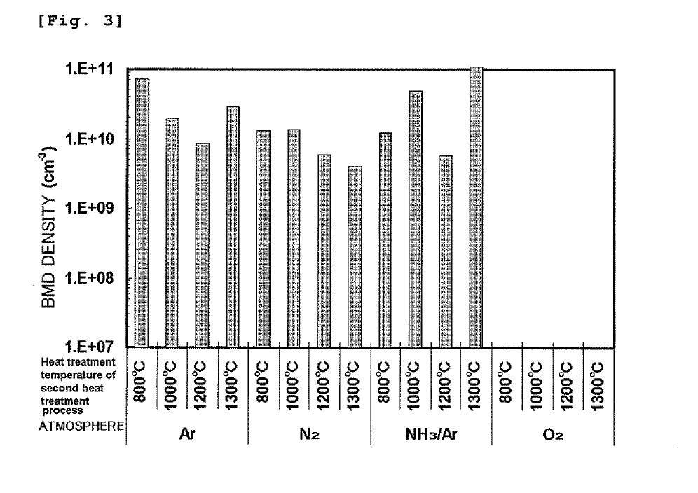

Moreover, simulation heat treatment of a flash memory fabrication process was performed on other wafers, and BMDs were formed in the wafers. Then, immersion in 5% HF was performed to remove an oxide film formed on the surface. Thereafter, etching was performed by an RIE apparatus, the number of residual projections was measured by using an electron microscope, and the defect density was calculated. A graph showing the relationship between the calculated BMD density and an temperature and an atmosphere in the second heat treatment process is shown in FIG. 3.

As shown in FIG. 3, the BMD densities of the wafers on which rapid heat treatment was performed in an atmosphere other than an atmosphere of O₂ gas were high on the whole; on the other hand, the BMD densities of the wafers on which rapid heat treatment was performed in an atmosphere of O₂ gas were below a minimum limit of detection due to the suppression of BMD formation. As described above, it is possible to control BMD formation at the time of device fabrication heat treatment easily by an atmosphere.

### Experimental Example

An N-region silicon single crystal ingot (diameter: 12 inches (300 mm), orientation <100>, conductivity type: p-type) was grown while applying a transverse magnetic field by the MCZ method by the silicon single crystal pulling apparatus of FIG. 1, and rapid heat treatment (the first heat treatment process) was performed on a plurality of silicon single crystal wafers cut from the grown ingot in each of an atmosphere of Ar gas, an atmosphere of N₂ gas, an atmosphere of NH₃/Ar gas, and an atmosphere of O₂ gas at 1250 to 1350° C. for 10 seconds by using the rapid heating/rapid cooling apparatus of FIG. 2 (here, Helios manufactured by Mattson Technology, Inc.) to annihilate RIE defects in a wafer surface layer.

The front surfaces of the wafers subjected to the heat treatment were polished to a depth of about 5 μm, and etching was performed by using a magnetron RIE apparatus (Centura manufactured by Applied Materials, Inc.). Then, a residual projection after etching was measured by a laser scattering foreign matter inspection apparatus (SP1 manufactured by KLA-Tencor Corporation), and the defect density was calculated. The results are shown in Table 2.

TABLE 2

| | First Temperature | | | |
|---|---|---|---|---|
| First Atmosphere | 1250° C. | 1290° C. | 1320° C. | 1350° C. |
| Ar | 189 | 46 | 0 | 0 |
| N₂ | 202 | 48 | 0 | 0 |
| NH₃/Ar | 219 | 52 | 0 | 0 |
| O₂ | 170 | 33 | 0 | 0 |

As is clear from Table 2, in the first heat treatment process, RIE defects are annihilated completely by rapid heat treatment at a temperature higher than 1300° C. Moreover, since these are the measurement results of defects on the surface polished to a depth of 5 μm, in this example, the defects at a depth of at least 5 μm from the surface are annihilated by the rapid heat treatment at a temperature higher than 1300° C.

Furthermore, the results of measurement of the lifetimes of the other wafers in the same manner as in the example are shown in Table 3.

TABLE 3

| First Atmosphere | 1250° C. | 1290° C. | 1320° C. | 1350° C. |
|---|---|---|---|---|
| Ar | Excellent | Good | Poor | Poor |
| NH₃/Ar | Good | Fair | Poor | Poor |

Ecellent . . . 1000 μsec or longer
Good . . . 700 μsec or longer and shorter than 1000 μsec
Fair . . . 400 μsec or longer and shorter than 700 μsec
Poor . . . shorter than 400 μsec

As is clear from Table 3, the higher the temperature, the shorter the lifetime, and, when the rapid heat treatment is performed at a temperature exceeding 1300° C., the lifetime is greatly shortened.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

1-7. (canceled)

8. A method for producing a silicon wafer, comprising at least:
a first heat treatment process in which rapid heat treatment is performed on a silicon wafer cut from a silicon single crystal ingot grown by the Czochralski method by using a rapid heating/rapid cooling apparatus in a first atmosphere containing at least one of nitride film formation atmospheric gas, rare gas, and oxidizing gas at a first temperature that is higher than 1300° C. and is lower than or equal to a silicon melting point for 1 to 60 seconds; and
a second heat treatment process in which, after the first heat treatment process, a temperature and an atmosphere are controlled so as to be a second temperature and a second atmosphere that suppress generation of a defect caused by a vacancy in the silicon wafer and rapid heat treatment is performed on the silicon wafer at the controlled second temperature in the controlled second atmosphere.

9. The method for producing a silicon wafer according to claim 8, wherein
in the second heat treatment process, after the first heat treatment process, the second heat treatment process is performed by lowering the temperature rapidly from the first temperature to the second temperature that is lower than 1300° C. at the rate of temperature fall of 5° C./sec or more but 150° C./sec or less and performing rapid heat treatment on the silicon wafer at the second temperature for 1 to 60 seconds.

10. The method for producing a silicon wafer according to claim 8, wherein
as the second atmosphere in the second heat treatment process, an atmosphere containing at least one of the rare gas and the nitride film formation atmospheric gas is used, and the second temperature is set at 300° C. or higher but lower than 1300° C.

11. The method for producing a silicon wafer according to claim 9, wherein
as the second atmosphere in the second heat treatment process, an atmosphere containing at least one of the rare gas and the nitride film formation atmospheric gas is used, and the second temperature is set at 300° C. or higher but lower than 1300° C.

12. The method for producing a silicon wafer according to claim 8, wherein
as the second atmosphere in the second heat treatment process, an atmosphere of reducing gas or a gas mixture of the reducing gas and the rare gas is used, and the second temperature is set at 300° C. or higher but lower than 900° C.

13. The method for producing a silicon wafer according to claim 9, wherein
as the second atmosphere in the second heat treatment process, an atmosphere of reducing gas or a gas mixture of the reducing gas and the rare gas is used, and the second temperature is set at 300° C. or higher but lower than 900° C.

14. The method for producing a silicon wafer according to claim 8, wherein
as the second atmosphere in the second heat treatment process, an atmosphere of oxidizing gas is used, and the second temperature is set at 300° C. or higher but 700° C. or lower or 1100° C. or higher but lower than 1300° C.

15. The method for producing a silicon wafer according to claim 9, wherein
as the second atmosphere in the second heat treatment process, an atmosphere of oxidizing gas is used, and the second temperature is set at 300° C. or higher but 700° C. or lower or 1100° C. or higher but lower than 1300° C.

16. The method for producing a silicon wafer according to claim 8, wherein
the silicon wafer is a silicon single crystal wafer cut from a silicon single crystal ingot whose whole surface is an OSF region, an N region, or a region in which the OSF region and the N region are mixed.

17. The method for producing a silicon wafer according to claim 9, wherein
the silicon wafer is a silicon single crystal wafer cut from a silicon single crystal ingot whose whole surface is an OSF region, an N region, or a region in which the OSF region and the N region are mixed.

18. The method for producing a silicon wafer according to claim 10, wherein
the silicon wafer is a silicon single crystal wafer cut from a silicon single crystal ingot whose whole surface is an OSF region, an N region, or a region in which the OSF region and the N region are mixed.

19. The method for producing a silicon wafer according to claim 11, wherein
the silicon wafer is a silicon single crystal wafer cut from a silicon single crystal ingot whose whole surface is an OSF region, an N region, or a region in which the OSF region and the N region are mixed.

20. The method for producing a silicon wafer according to claim 12, wherein
the silicon wafer is a silicon single crystal wafer cut from a silicon single crystal ingot whose whole surface is an OSF region, an N region, or a region in which the OSF region and the N region are mixed.

21. The method for producing a silicon wafer according to claim 13, wherein
the silicon wafer is a silicon single crystal wafer cut from a silicon single crystal ingot whose whole surface is an OSF region, an N region, or a region in which the OSF region and the N region are mixed.

22. The method for producing a silicon wafer according to claim 14, wherein
the silicon wafer is a silicon single crystal wafer cut from a silicon single crystal ingot whose whole surface is an OSF region, an N region, or a region in which the OSF region and the N region are mixed.

23. The method for producing a silicon wafer according to claim 15, wherein
the silicon wafer is a silicon single crystal wafer cut from a silicon single crystal ingot whose whole surface is an OSF region, an N region, or a region in which the OSF region and the N region are mixed.

24. A silicon wafer produced by the method for producing a silicon wafer according to claim 8, wherein
a defect that is detected by an RIE method is not present at a depth of at least 1 μm from the surface of the silicon wafer which becomes a device fabrication region, and the lifetime of the silicon wafer is 500 μsec or longer.
